(19) United States
(12) Patent Application Publication
(10) Pub. No.: US 2023/0018624 A1
(43) Pub. Date: Jan. 19, 2023

(54) ACTUATOR AND OPTICAL REFLECTIVE ELEMENT

(71) Applicant: Panasonic Intellectual Property Management Co., Ltd., Osaka (JP)

(72) Inventors: Kazuki KOMAKI, Osaka (JP); Ryouichi TAKAYAMA, Osaka (JP); Kensuke MIHARA, Osaka (JP)

(21) Appl. No.: 17/945,760

(22) Filed: Sep. 15, 2022

Related U.S. Application Data
(63) Continuation of application No. PCT/JP2021/012090, filed on Mar. 23, 2021.

(30) Foreign Application Priority Data
Mar. 30, 2020 (JP) 2020-059530

(51) Int. Cl. G02B 26/08; G02B 26/10

(52) U.S. Cl. CPC G02B 26/0858; G02B 26/101

(57) ABSTRACT

An actuator that includes: a first driving body that includes a first piezoelectric material that extends in a first axis direction; a second driving body that includes a second piezoelectric material shorter than the first piezoelectric material in the first axis direction; and a base that holds the first driving body and the second driving body at proximal end portions of the first driving body and the second driving body in the first axis direction. The first driving body and the second driving body are aligned and coupled together in a polarization axis direction in a state in which a polarization axis of the first piezoelectric material and a polarization axis of the second piezoelectric material correspond with each other. A length of the second piezoelectric material in a second axis direction is greater than a length of the first piezoelectric material in the second axis direction.

### CROSS REFERENCE TO RELATED APPLICATIONS

This is a continuation application of PCT International Application No. PCT/JP2021/012090 filed on Mar. 23, 2021, designating the United States of America, which is based on and claims priority of Japanese Patent Application No, 2020-059530 filed on Mar. 30, 2020, The entire disclosures of the above-identified applications, including the specifications, drawings and claims are incorporated herein by reference in theft entirety.

### FIELD

The present disclosure relates to an actuator including a piezoelectric material, and an optical reflective element including the actuator.

### BACKGROUND

Actuators including a piezoelectric material apply an electric field to the piezoelectric material to expand and contract the piezoelectric material for generating a driving force. Actuators having a unimorph structure include a plate joined to one surface of a piezoelectric material which does not expand nor contract in the expansion and contraction direction of the piezoelectric material, and convert expansion and contraction of the piezoelectric material with respect to the plate into warping of the plate. In addition, actuators having a bimorph structure include two piezoelectric materials that are joined together such that polarization directions are in mutually opposite directions, and cause the entire actuator to warp by expansion of one of the two piezoelectric materials and contraction of the other of the two piezoelectric materials.

An actuator disclosed in Patent Literature (PTL) 1 is an actuator having a unimorph structure. The actuator having a cantilever structure in which the proximal end portion is fixed uses displacement of the distal end portion caused by warping for changing an angle of a mirror.

### CITATION LIST

### Patent Literature

PTL 1: International Publication No. 2013/114857

### SUMMARY

### Technical Problem

However, due to typical characteristics of a piezoelectric material, an amount of displacement and a generating force are in the trade-off relationship in actuators including a piezoelectric material. Accordingly, the realization of an actuator having a large amount of displacement and a strong generating force has been difficult.

In view of the above, the present disclosure aims to provide an actuator capable of reconciling a large amount of displacement with a strong generating force, and an optical reflective element including the actuator.

### Solution to Problem

In order to provide such an actuator, an actuator according to one aspect of the present disclosure includes: a first driving body that includes a first piezoelectric material that extends in a first axis direction intersecting with a polarization axis; a second driving body that includes a second piezoelectric material shorter than the first piezoelectric material in the first axis direction; and a base that holds the first driving body and the second driving body at proximal end portions of the first driving body and the second driving body in the first axis direction. The first driving body and the second driving body are aligned and coupled together in a polarization axis direction in a state in which a polarization axis of the first piezoelectric material and a polarization axis of the second piezoelectric material substantially correspond with each other. At least one of the following holds true: a length of the second piezoelectric material in a second axis direction is greater than or equal to a length of the first piezoelectric material in the second axis direction, the second axis direction being orthogonal to the polarization axis and the first axis direction; or a length of the second piezoelectric material in the polarization axis direction is greater than or equal to a length of the first piezoelectric material in the polarization axis direction.

### Advantageous Effects

According to an actuator of the present disclosure, a large amount of displacement and a large generating force can be obtained.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a perspective view of an actuator according to Embodiment 1.

FIG. 2 is a top view of the actuator according to Embodiment 1.

FIG. 3 is a side view of the actuator according to Embodiment 1.

FIG. 4 is a diagram illustrating operations of the actuator according to Embodiment 1.

FIG. 5 is a side view of an actuator according to Embodiment 2.

FIG. 6 is a top view of the actuator according to Embodiment 2.

FIG. 7 shows side views for illustrating polarization processing steps according to Embodiment 2.

FIG. 8 is a side view illustrating expansion and contraction of piezoelectric materials during actuator driving time 1 according to Embodiment 2.

FIG. 9 is a side view illustrating expansion and contraction of the piezoelectric materials during actuator driving time 2 according to Embodiment 2.

FIG. 10 is a graph showing temporal changes in voltages applied to the piezoelectric materials when the actuator according to Embodiment 2 is driven,

FIG. 11 is a perspective view of an optical reflective element according to Embodiment 3.

FIG. 12 is a side view of another example of an actuator.

### DESCRIPTION OF EMBODIMENTS

Hereinafter, an embodiment of an actuator according to the present disclosure and an optical reflective element using the actuator will be described with reference to the drawings. The numerical values, shapes, materials, structural elements, the positional relationship and connection state of the structural elements, steps, orders of the steps etc. illustrated in the following embodiments are mere examples, and thus are not intended to limit the present disclosure. Moreover, although the following may describe a plurality of inventions as one embodiment, a structural element not recited in the claims is described as an optional structural element for the invention according to the claim. In order to describe the present disclosure, the drawings are schematic diagrams in which the structural elements are emphasized, omitted, and/or proportionally adjusted as appropriate. For this reason, the structural elements may have shapes, positional relationships, and proportions which are different from the actual shapes, actual positional relationships, and actual proportions.

### Embodiment 1

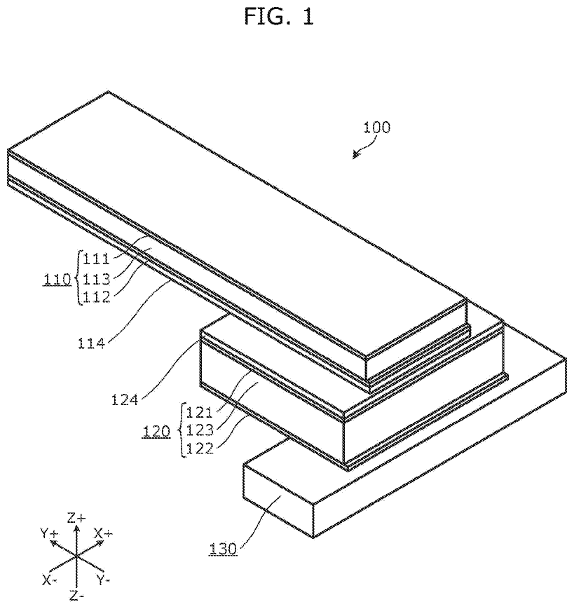

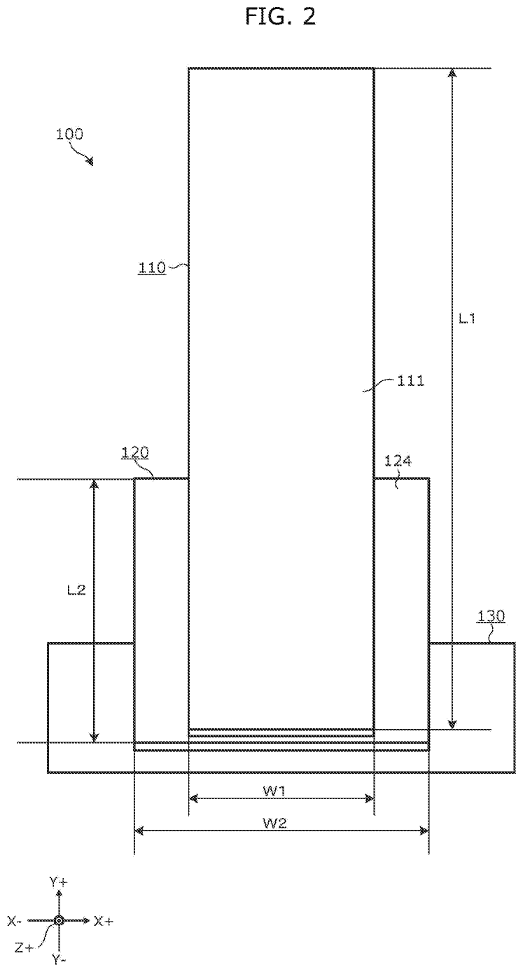

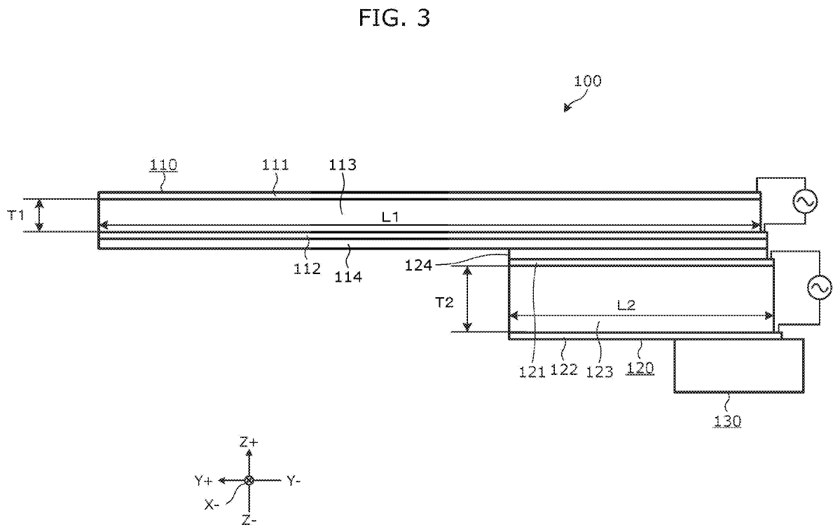

FIG. 1 is a perspective view of an actuator according to Embodiment 1. FIG. 2 is a top view of the actuator according to Embodiment 1. FIG. 3 is a side view of the actuator according to Embodiment 1. Actuator 100 is a driving source of a cantilever structure in which a proximal end portion (an end portion on the negative side of the Y axis as shown in the diagrams) is held and a distal end portion (an end portion on the positive side of the Y axis as shown in the diagrams) is caused to displace. Actuator 100 includes first driving body 110, second driving body 120, and base 130. In Embodiment 1, actuator 100 includes first converting member 114 and second converting member 124.

First driving body 110 is a member that, with the application of an electric field, expands and contracts in a distal direction with respect to a proximal end portion that is fixed. First driving body 110 includes first piezoelectric material 113, first electrode 111, and second electrode 112.

First piezoelectric material 113 is the so-called piezoelectric element whose polarization corresponds with a direction (the Z axis direction as shown in the diagrams) in which first electrode 111 and second electrode 112 are aligned. Although the shape of first piezoelectric material 113 is not particularly limited, first piezoelectric material 113 in Embodiment 1 is of a parallelepiped-like shape. The parallelepiped-like shape includes a parallelepiped, and further includes a shape whose portion is, for example, protruded, notched, rounded, and/or slanted as long as the shape as a whole appears to be a parallelepiped. First piezoelectric material 113 extends in a first axis direction (the Y axis direction as shown in the drawings) that intersects with a polarization axis (the Z axis as shown in the drawings). The length in the first axis direction is set to L1, the length in the polarization axis direction is set to T1, and the length in a second axis direction (the X axis direction as shown in the drawings) that is orthogonal to the polarization axis and a first axis is set to W1. Moreover, the following expressions are satisfied: L1>T1, and L1>W1.

First electrode 111 and second electrode 112 each are an electrode for applying an electric field to first piezoelectric material 113. First electrode 111 is disposed on one end face side of first piezoelectric material 113 in the polarization direction, and second electrode 112 is disposed on the other end face side of first piezoelectric material 113 in the polarization direction, First electrode 111 and second electrode 112 each are of a quadrilateral, sheet-like shape that is substantially the same as the shape of a face of first piezoelectric material 113 which has the maximum area size. The phrase substantially the same shape includes the same shape. Furthermore, so long as a shape as a whole appears to be the shape of the above-described face, substantially the same shape also includes a shape whose portion is, for example, notched, pierced, and/or rounded. Note that a portion protruded from first piezoelectric material 113 is not a portion that applies an electric field to first piezoelectric material 113 even if the portion is integral with first electrode 111 or second electrode 112. For this reason, first electrode 111 and second electrode 112 do not include the protruded portion.

First converting member 114 is a member that converts expansion and contraction of first piezoelectric material 113 having a unimorph structure in the first axis direction into bending in the polarization axis direction. In the first axis direction, first converting member 114 maintains its predetermined length against expansion and contraction of first piezoelectric material 113, and in the polarization direction, first converting member 114 has flexibility that allows bending. Although a material included in first converting member 114 is not particularly limited, steel products, silicone, or ceramics including resin or oxide exemplify the material. Moreover, when an electric conductor is used for first converting member 114, insulation processing such as providing of a film having insulation properties on a member that is the electric conductor may be performed to be insulated from second electrode 112. Moreover, second electrode 112 can also perform the function of first converting member 114, in addition to its own function.

Although the shape of first converting member 114 is not particularly limited, it is suitable for first converting member 114 to have a length that is approximately the same as the length of first piezoelectric material 113 in the first axis direction. In Embodiment 1, first converting member 114 is of a quadrilateral, plate-like shape that is substantially the same as the shape of the face of first piezoelectric material 113 which has the maximum area size.

Second driving body 120 is a member that is shorter than first driving body 110 in the first axis direction, and, with the application of an electric field, expands and contracts in the distal direction with respect to a proximal end portion that is fixed. Second driving body 120 includes second piezoelectric material 123, third electrode 121, and fourth electrode 122.

Second piezoelectric material 123 is the so-called piezoelectric element whose polarization corresponds with a direction (the Z axis direction as shown in the diagrams) in which third electrode 121 and fourth electrode 122 are aligned. Although the shape of second piezoelectric material 123 is not particularly limited, second piezoelectric material 123 in Embodiment 1 is of a parallelepiped-like shape. Second piezoelectric material 123 expands in the first axis direction (the Y axis direction as shown in the drawings) that intersects with the polarization axis (the Z axis as shown in the drawings). The length in the first axis direction is set to L2, the length in the polarization axis direction is set to T2, and the length in the second axis direction (the X axis direction as shown in the drawings) orthogonal to the polarization axis and the first axis is set to W2. Moreover, the following expressions are satisfied: L1>L2, and at least one of T1≤T2 and W1≤W2.

Conditions for realizing actuator 100 having large displacement and a great generating force are as follows: (i) first piezoelectric material 113 is to have large displacement, and (ii) second piezoelectric material 123 is to generate a large force. Although it is possible to realize the above-described actuator 100 by simply using second piezoelectric material 123 and first piezoelectric material 113 having different shapes in the case where a material included in second piezoelectric material 123 and a material included in first piezoelectric material 113 are substantially the same, first piezoelectric material 113 and second piezoelectric material 123 in this embodiment include mutually different materials to enhance advantageous effects, Specifically, when an electric field having the same intensity is applied to each of first piezoelectric material 113 and second piezoelectric material 123 having the same shape and the same size, displacement of a material included in first piezoelectric material 113 is larger than displacement of a material included in second piezoelectric material 123, and a generating force produced by the material included in second piezoelectric material 123 is larger than a generating force produced by the material included in first piezoelectric material 113, For example, first piezoelectric material 113 may include a soft-type material that is typically considered to be capable of obtaining large displacement, and second piezoelectric material 123 may include a hard-type material that is typically considered to be capable of generating a great force. As a method of distinguishing between a soft-type material and a hard-type material, a material having a mechanical quality factor of less than 300 may be considered as a soft-type material, and a material having a mechanical quality factor of more than or equal to 300 may be considered as a hard-type material, for example.

Third electrode 121 and fourth electrode 122 each are an electrode for applying an electric field to second piezoelectric material 123. Third electrode 121 is disposed on one end face side of second piezoelectric material 123 in the polarization direction, and fourth electrode 122 is disposed on the other end face side of second piezoelectric material 123 in the polarization direction. Third electrode 121 and fourth electrode 122 each are of a quadrilateral, sheet-like shape that is substantially the same as the shape of a face of second piezoelectric material 123 which has the maximum area size.

Second converting member 124 is the same as first converting member 114, and is a member that converts expansion and contraction of second piezoelectric material 123 having a unimorph structure in the first axis direction into bending in the polarization axis direction, Note that third electrode 121 is capable of performing the function of second converting member 124, in addition to its own function. Although the shape of second converting member 124 is not particularly limited, it is suitable for second converting member 124 to have a length that is approximately the same as the length of second piezoelectric material 123 in the first axis direction. In Embodiment 1, second converting member 124 is of a quadrilateral, plate-like shape that is substantially the same as the shape of the face of second piezoelectric material 123 which has the maximum area size.

Base 130 holds first driving body 110 and second driving body 120 at proximal end portions of first driving body 110 and second driving body 120 in the first axis direction. In this embodiment, base 130 is connected to second driving body 120 at the proximal end portion of the face of second driving body 120 which has the maximum area size, in a state in which the face of base 130 and the face of second driving body 120 are in contact with each other. First driving body 110 is disposed such that the proximal end portion of first driving body 110 and base 130 overlap in the first axis direction. First driving body 110 is held by base 130 via second driving body 120.

The shape and structure of base 130 are not particularly limited. In Embodiment 1, base 130 is of a parallelepiped-like shape that extends in the second axis direction (the X axis direction as shown in the diagrams), and has a length greater than the length of first driving body 110 and the length of second driving body 120 in the second axis direction. In the first axis direction, base 130 is disposed such that base 130 protrudes further out than the proximal end face of first driving body 110 and the proximal end face of second driving body 120. A role of a base is to hold a first driving body and a second driving body. Accordingly, other than the disposition described in Embodiment 1, the driving bodies and the base may be connected at end faces of the first driving body and the second driving body which are on the negative side of the first axis direction (the negative side of the Y axis direction).

First driving body 110 and second driving body 120 are aligned and coupled together in the polarization axis direction (the Z axis direction as shown in the diagrams) in a state in which the polarization axis of first piezoelectric material 113 and the polarization axis of second piezoelectric material 123 substantially correspond with each other. The proximal end face of first driving body 110 and the proximal end face of second driving body 120 are substantially aligned in the first axis direction. The phrase substantially aligned includes perfect alignment, a deviation due to exposing of an electrode, etc. The proximal end portion of the face of first driving body 110 which has the maximum area size in the first axis direction and the center portion of the face of second driving body 120 which has the maximum area size in the first axis direction are coupled together, in a state in which the face of first driving body 110 and the face of second driving body 120 are in contact with each other.

A method for manufacturing actuator 100 is not particularly limited. Moreover, the method for manufacturing actuator 100 differs depending on the size and application of actuator 100, and performance desired for actuator 100. For example, actuator 100 may be manufactured by joining parts together after each of the parts are separately produced. In addition, actuator 100 may be manufactured using a technique for producing micro electro mechanical systems (MEMS). Moreover, first converting member 114 and second converting member 124 may be shared. With this configuration, actuator 100 can be more readily manufactured.

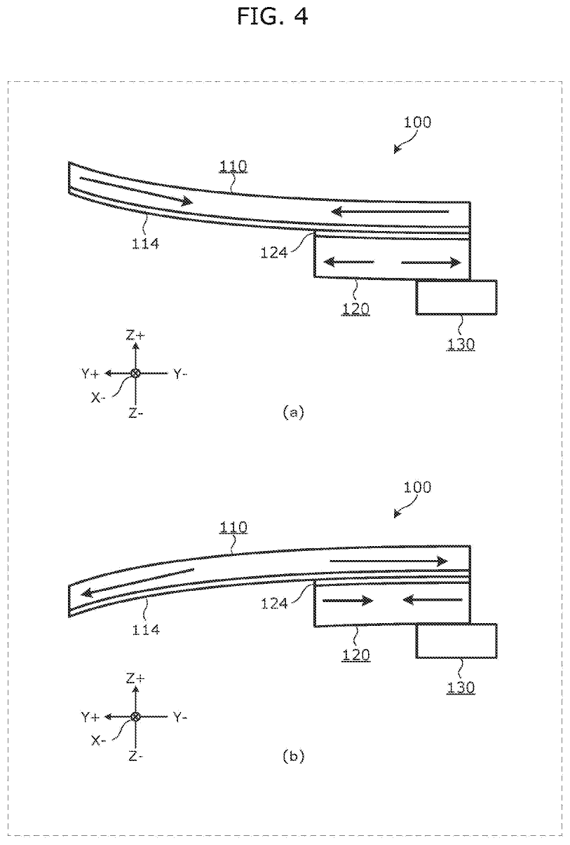

FIG. 4 is a diagram illustrating operations of the actuator. As illustrated in (a) of FIG. 4, when an electric field is applied such that first piezoelectric material 113 contracts with respect to first converting member 114 in the first axis direction (the Y axis direction as shown in the diagrams), first driving body 110 warps and the distal end of first driving body 110 displaces in a direction (the positive side of the Z axis direction as shown in the diagrams) farther away from base 130 in the polarization axis direction. Moreover, when an electric field is applied such that second piezoelectric material 123 expands with respect to second converting member 124 in the first axis direction (the Y axis direction as shown in the diagrams), second driving body 120 warps in the same direction as first driving body 110 and the distal end of second driving body 120 displaces in a direction (the positive side of the Z axis direction as shown in the diagrams) farther away from base 130 in the polarization axis direction.

The above operations realize a large amount of displacement in the distal end portion of first driving body 110 that is comparatively long in the first axis direction. Moreover, in second driving body 120 that is comparatively short in the first axis direction and long in the polarization axis direction (thickness direction) and the second axis direction (width direction), a force larger than a force generated by first driving body 110 is generated. This force is added to a force generated by first driving body 110, thereby generating a force that cannot be generated only by first driving body 110. In addition, compared to the case where the length of second driving body 120 and the length of first driving body 110 are the same, shortening of only second driving body 120 can realize actuator 100 that can generate a large generating force without a reduction in an amount of displacement of the distal end portion. Furthermore, compared to the case where the length of second driving body 120 and the length of first driving body 110 are the same, shortening of only second driving body 120 can reduce the mass of a distal end portion and can increase the natural vibration frequency of actuator 100.

On the other hand, as illustrated in (b) of FIG. 4, when an electric field opposite to the above-mentioned electric field is applied such that first piezoelectric material 113 expands with respect to first converting member 114 in the first axis direction, first driving body 110 warps and the distal end of first driving body 110 displaces in a direction (the negative side of the Z axis direction as shown in the diagrams) closer to base 130 in the polarization axis direction. Moreover, when an opposite electric field is applied such that second piezoelectric material 123 contracts with respect to second converting member 124 in the first axis direction, second driving body 120 warps in the same direction as first driving body 110 and the distal end of second driving body 120 displaces in a direction (the negative side of the Z axis direction as shown in the diagrams) closer to base 130 in the polarization axis direction.

With the above-described operations, an amount of displacement at the distal end of first driving body 110 is also large, and a force that cannot be generated only by first driving body 110 can be generated. Furthermore, compared to the case where the length of second driving body 120 and the length of first driving body 110 are the same, shortening only second driving body 120 can realize actuator 100 having a large amount of displacement at the distal end without significantly reducing a generating force. Moreover, compared to the case where the length of second driving body 120 and the length of first driving body 110 are the same, shortening of only second driving body 120 can reduce the mass of a distal end portion and can increase the natural vibration frequency of actuator 100, In addition, an application of an alternating electric field to each of first driving body 110 and second driving body 120 can alternately repeat the state illustrated in (a) of FIG. 4 and the state illustrated in (b) of FIG. 4. With this, it is possible to cause the distal end of first driving body 110 included in actuator 100 to vibrate with large strokes and a large generating force.

### Embodiment 2

Actuator 100 according to another embodiment will be described. Note that elements (parts) having the same effect, the same function, the same shape, the same mechanism, and/or the same structure as the elements (parts) described in the above-described Embodiment 1 are given the same reference numerals, and descriptions of these elements may be omitted. In addition, the following mainly describes points different from Embodiment 1, thereby omitting descriptions of the same details.

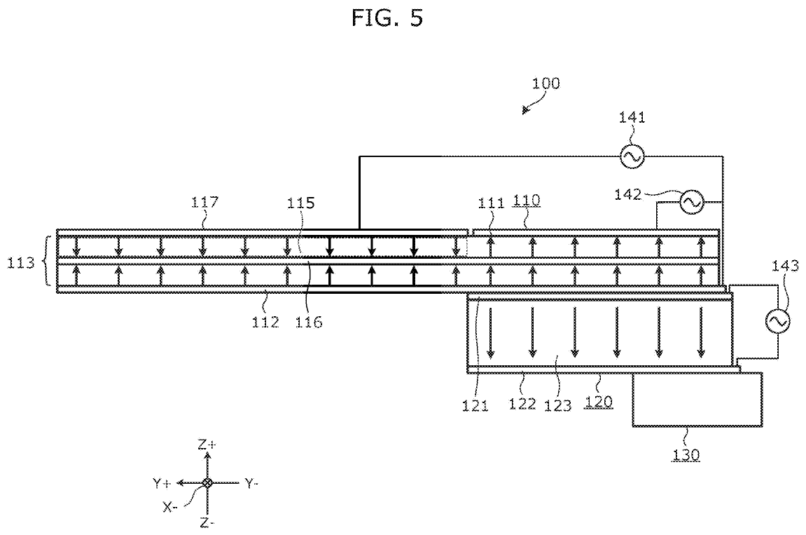

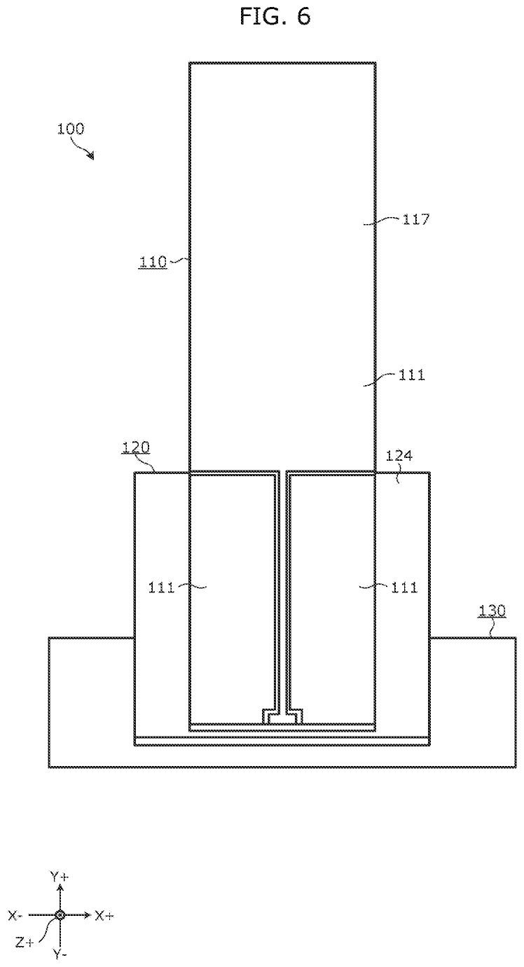

FIG. 5 is a side view of an actuator according to Embodiment 2. FIG. 6 is a top view of the actuator according to Embodiment 2. Arrows drawn inside first piezoelectric material 113 and second piezoelectric material 123 illustrated in FIG. 5 denote polarization directions.

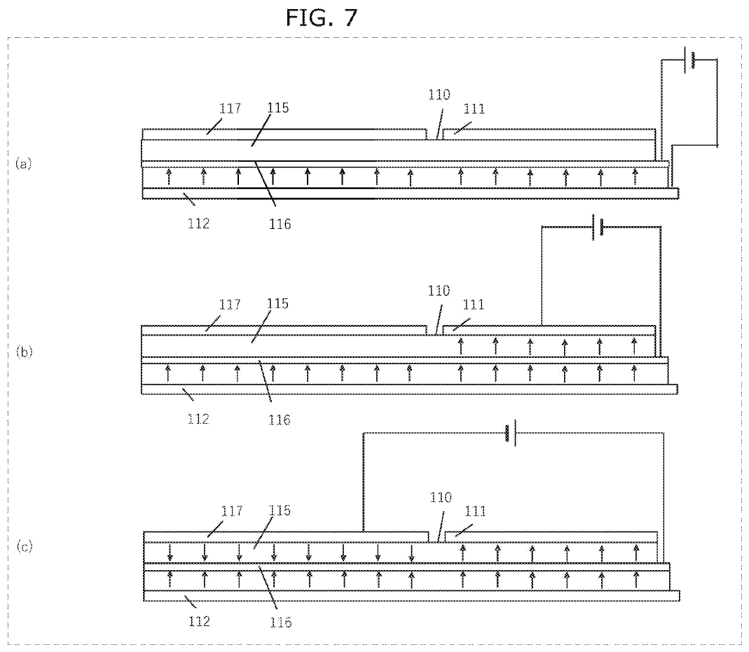

First piezoelectric material 113 is divided into two layers at least in the distal end portion. One of the two divided layers is reverse polarization layer 115 whose polarization direction is opposite of the polarization direction of the other of the two divided layer. In other words, the distal end portion of first piezoelectric material 113 has, solely by itself, a bimorph structure, and the proximal end portion and second piezoelectric material 123 are stacked to have the bimorph structure. In Embodiment 2, the entire first piezoelectric material 113 is divided into two layers in the polarization axis direction. Reverse polarization layer 115 extends from the distal end to a position corresponding to the distal end face of second piezoelectric material 123. In between the two layers of first piezoelectric material 113, intermediate electrode 116 is disposed. Moreover, first driving body 110 includes, on the surface of a position corresponding to reverse polarization layer 115, distal end electrode 117 for applying an electric field only to the distal end portion of first driving body 110. In order to locally polarize first piezoelectric material 113, polarization processes are performed step by step. FIG. 7 shows side views for illustrating polarization processing steps according to Embodiment 2. First, an electric field is applied between second electrode 112 and intermediate electrode 116 to cause polarization directions of a piezoelectric material between the aforementioned electrodes correspond with one another (see (a) of FIG. 7). Next, an electric field is applied between first electrode 111 and intermediate electrode 116 such that polarization directions of a piezoelectric material between first electrode 111 and intermediate electrode 116 are the same as the polarization directions of the piezoelectric material between second electrode 112 and intermediate electrode 116 (see (b) of FIG. 7). Then, in order to form reverse polarization layer 115 in the distal end portion of first piezoelectric material 113, an electric field is applied between intermediate electrode 116 and distal end electrode 117 such that polarization directions are opposite of the polarization directions of the piezoelectric material between second electrode 112 and intermediate electrode 116 (see (c) of FIG. 7).

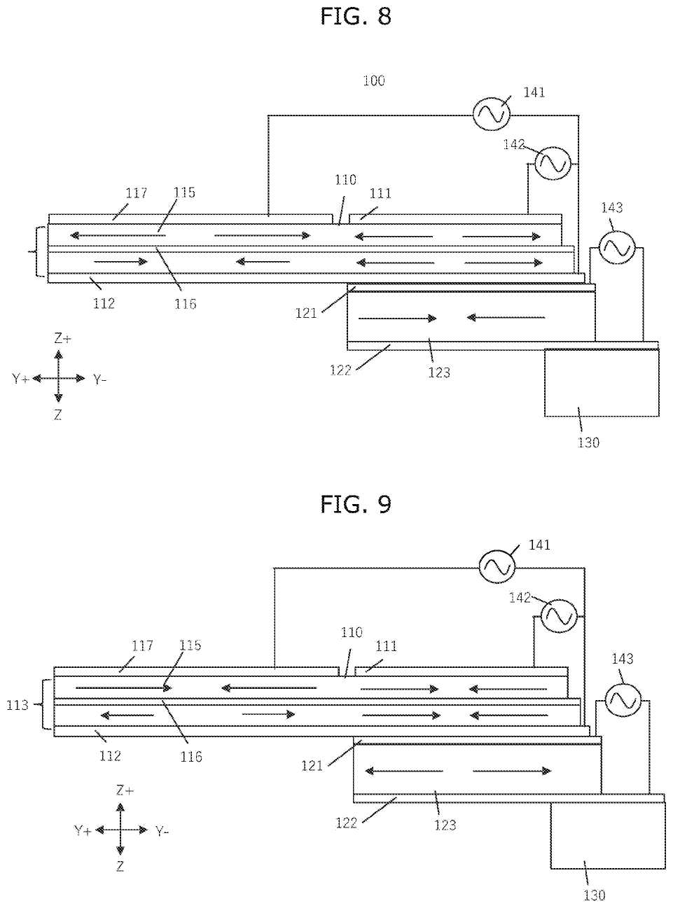

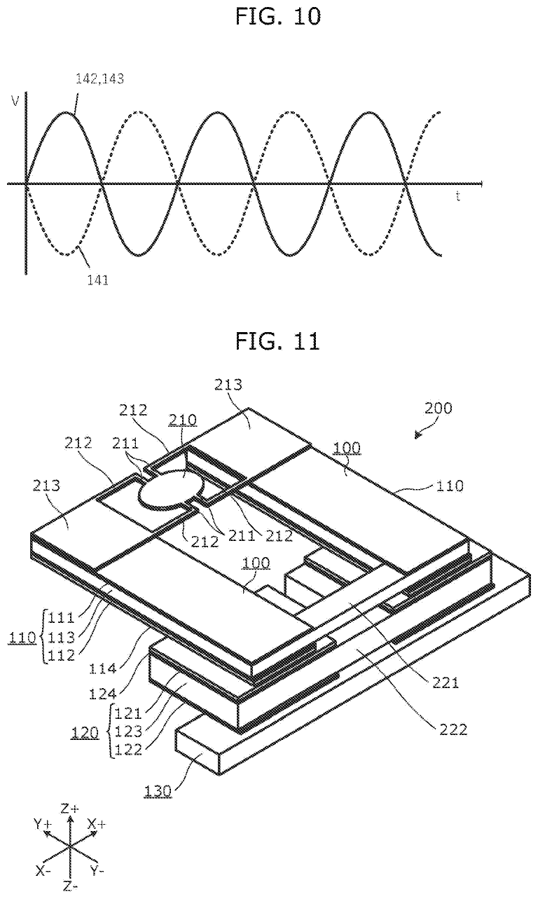

FIG. 8 is a side view illustrating expansion and contraction of piezoelectric materials during actuator driving time 1 according to Embodiment 2, FIG. 9 is a side view illustrating expansion and contraction of the piezoelectric materials during actuator driving time 2 according to Embodiment 2. Here, arrows drawn inside first piezoelectric material 113 and second piezoelectric material 123 illustrated in FIG. 8 and FIG. 9 denote directions of expansion and contraction of the piezoelectric materials. Second electrode 112 of first driving body 110 and third electrode 121 of second driving body 120 in contact with second electrode 112 have a ground potential. As illustrated in FIG. 10, an in-phase electric field is applied by each of power source 142 and power source 143, and an anti-phase electric field that is 180 degrees reverse of the in-phase electric field is also applied by power source 141, With the application of alternating currents by power sources 141, 142, and 143 using the above-described electric-field application method, actuator 100 is repeatedly amplified in the positive and negative sides of the Z axis direction.

Actuator 100 according to Embodiment 2 does not require a converting member, therefore actuator 100 can be readily manufactured. Moreover, a portion of second electrode 112 included in first driving body 110 may be included as third electrode 121 included in second driving body 120, With this configuration, actuator 100 can be more readily manufactured.

### Embodiment 3

Next, an embodiment of optical reflective element 200 will be described. Note that elements (parts) having the same effect, the same function, the same shape, the same mechanism, and/or the same structure as the above-described Embodiments 1 and 2 are given the same reference numerals, and descriptions of these elements may be omitted. In addition, the following mainly describes points different from Embodiments 1 and 2, thereby omitting descriptions of the same details.

FIG. 11 is a perspective view of an optical reflective element according to Embodiment 3. Optical reflective element 200 is used for a projector and the like that project an image etc. by periodically changing a reflection angle of laser light and sweeping positions irradiated with the light, for example. Optical reflective element 200 includes a plurality of actuators 100 and reflective body 210.

Actuators 100 included in optical reflective element 200 are not particularly limited as long as the actuators relate to the present disclosure. In Embodiment 3, two actuators 100 each having a structure exemplified in Embodiment 1 are used. In optical reflective element 200, the two actuators 100 are disposed such that the first axis directions (the Y axis directions as shown in the diagrams) and the polarization axis directions (the Z axis directions as shown in the diagrams) are parallel with each other. Moreover, the proximal end faces of first piezoelectric materials 113 are disposed in the same plane, and the proximal end faces of second piezoelectric materials 123 are disposed in the same plane.

The proximal end portions of first piezoelectric materials 113 included in the two actuators 100 are integrally coupled together by first coupler 221. With this, it is possible to ensure the mutual positional accuracy of the distal end portions of the two first driving bodies 110, and thus reflective body 210 can be attached with high positional accuracy. Therefore, highly accurate optical reflective element 200 can be stably manufactured.

In Embodiment 3, proximal end portions of second piezoelectric materials 123 are also integrally coupled together by second coupler 222. Moreover, base 130 has a length that collectively holds the two first driving bodies 110 and the two second driving bodies 120. With this, it is possible to increase the accuracy of attaching the two first driving bodies 110 that are made integral by first coupler 221 and the two second driving bodies 120 that are made integral by second coupler 222.

Reflective body 210 is a member that is connected, like a bridge, between the distal ends of first driving bodies 110 included in the plurality of actuators 100. Reflective body 210 is a member that rotationally oscillates (repetitively rotationally vibrates) about a first axis in the center portion between the distal ends of the two first driving bodies 110, and reflects light. Although the shape of reflective body 210 is not particularly limited, reflective body 210 in this embodiment is of a circular, plate-like shape. Reflective body 210 includes a mirror (not illustrated) on its surface which can reflect light to be reflected with high reflectance. A material used for the mirror can be optionally selected. A metal or a metallic compound, such as gold, silver, and aluminum exemplify the material. The mirror can be provided by smoothly polishing a surface of reflective body 210. The mirror need not have a flat surface. The mirror may have a curved surface.

Reflective body 210 includes rotational axes 211, beams 212, and joining portions 213 to be connected with the distal ends of the two first driving bodies 110 like a bridge.

Rotational axes 211 each are a bar-like member disposed along the first axis. One end portion of each rotational axis 211 is coupled to reflective body 210, and the other end of each rotational axis 211 is coupled to respective beams 212, Rotational axes 211 each are a member that transmits, to reflective body 210, torque for causing reflective body 210 to rotationally oscillate. Rotational axes 211 twist around the first axis to cause reflective body 210 to rotationally oscillate while holding reflective body 210. In Embodiment 3, rotational axes 211 are two separated rotational axes in a second axis direction (the X axis direction as shown in the diagrams), and the concentration of stress during twisting is reduced.

Beams 212 each are a part that connects, like a bridge, rotational axis 211 and joining portion 213 attached at the distal end of actuator 100. In Embodiment 3, beams 212 are disposed such that beams 212 protrude from end portions of the two separated rotational axes 211 toward joining portions 213.

Joining portions 213 each are a part that joins to the distal end portion of first driving body 110 included in actuator 100, Joining portions 213 each are of a quadrilateral, plate-like shape, and in contact with a large area of first driving body 110 to ensure strong adhesion.

In the above-described optical reflective element 200, the distal ends of the two actuators 100 are caused to vibrate in opposite phase to cause reflective body 210 to rotationally vibrate about the first axis direction. Moreover, since optical reflective element 200 uses actuators 100 whose distal ends greatly amplify and which produces a strong generating power to cause reflective body 210 to rotationally vibrate, a range (rotational angle) of a rotational vibration produced by reflective body 210 can be increased.

Note that the present disclosure is not limited to the above-described embodiments. For example, the present disclosure may include different embodiments realized by (i) optionally combining the structural elements described in the specification, and (ii) excluding some of the structural elements described in the specification. Moreover, the present disclosure also includes variations achieved by applying various modifications conceivable to those skilled in the art to each of the embodiments etc, without departing from the essence of the present disclosure, or in other words, without departing from the meaning of wording recited in the claims.

For example, in Embodiment 1, second piezoelectric material 123 is described as having length T in the polarization axis direction and length W in the second axis direction that are greater than those of first piezoelectric material 113. However, only one of the following may be held true: length T of second piezoelectric material 123 is greater than or equal to that of first piezoelectric material 113; and length W of second piezoelectric material 123 is greater than or equal to that of first piezoelectric material 113.

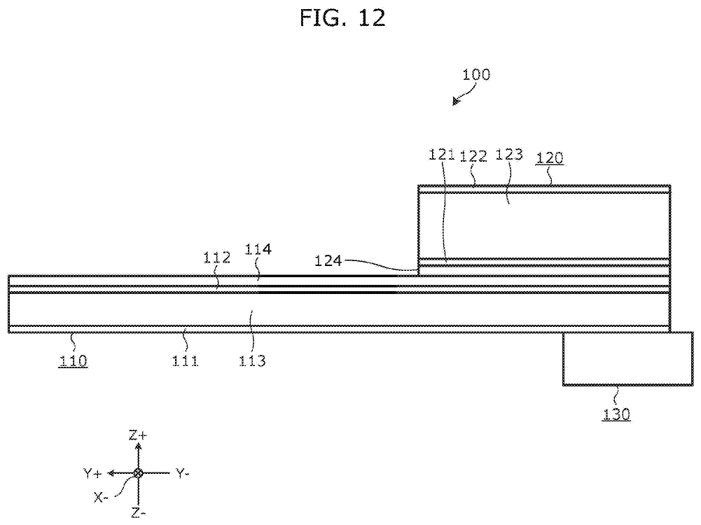

In addition, as illustrated in FIG. 12, second driving body 120 may be disposed at a position farther away with respect to base 130 than first driving body 110 is disposed.

Moreover, in Embodiment 2, second piezoelectric material 123 having a bimorph structure may be used.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure can be used for a device operated by a small actuator, a projector that displays an image by causing laser light to reflect, etc.

1. An actuator comprising:
a first driving body that includes a first piezoelectric material that extends in a first axis direction intersecting with a polarization axis;
a second driving body that includes a second piezoelectric material shorter than the first piezoelectric material in the first axis direction; and
a base that holds the first driving body and the second driving body at proximal end portions of the first driving body and the second driving body in the first axis direction, wherein
the first driving body and the second driving body are aligned and coupled together in a polarization axis direction in a state in which a polarization axis of the first piezoelectric material and a polarization axis of the second piezoelectric material substantially correspond with each other, and
at least one of the following holds true: a length of the second piezoelectric material in a second axis direction is greater than or equal to a length of the first piezoelectric material in the second axis direction, the second axis direction being orthogonal to the polarization axis and the first axis direction; or a length of the second piezoelectric material in the polarization axis direction is greater than or equal to a length of the first piezoelectric material in the polarization axis direction.

2. The actuator according to claim 1, wherein
when an electric field having same intensity is applied to each of the first piezoelectric material and the second piezoelectric material that have same shape and same size,
displacement of a material included in the first piezoelectric material is larger than displacement of a material included in the second piezoelectric material, and
a force generated by the material included the second piezoelectric material is larger than a force generated by the material included in the first piezoelectric material.

3. The actuator according to claim 1, wherein
a part or an entirety of the first piezoelectric material is divided into two layers in the polarization axis direction, and
at least a part of one of the two layers is a reverse polarization layer whose polarization direction is opposite of a polarization direction of an other of the two layers.

4. The actuator according to claim 2, wherein
a part or an entirety of the first piezoelectric material is divided into two layers in the polarization axis direction, and
at least a part of one of the two layers is a reverse polarization layer whose polarization direction is opposite of a polarization direction of an other of the two layers.

5. The actuator according to claim 3, wherein
the first driving body includes the first piezoelectric material, and a first electrode and a second electrode that are disposed in the polarization axis direction of the first piezoelectric material with the first piezoelectric material interposed therebetween for applying an electric field, and
at least one of the first electrode or the second electrode is electrically separated into two or more electrodes.

6. The actuator according to claim 4, wherein
the first driving body includes the first piezoelectric material, and a first electrode and a second electrode that are disposed in the polarization axis direction of the first piezoelectric material with the first piezoelectric material interposed therebetween for applying an electric field, and
at least one of the first electrode or the second electrode is electrically separated into two or more electrodes.

7. An optical reflective element comprising:
a plurality of actuators each of which includes:
a first driving body that includes a first piezoelectric material that extends in a first axis direction intersecting with a polarization axis;
a second driving body that includes a second piezoelectric material shorter than the first piezoelectric material in the first axis direction; and
a base that holds the first driving body and the second driving body at proximal end portions of the first driving body and the second driving body in the first axis direction, wherein
the first driving body and the second driving body are aligned and coupled together in a polarization axis direction in a state in which a polarization axis of the first piezoelectric material and a polarization axis of the second piezoelectric material substantially correspond with each other,
at least one of the following holds true: a length of the second piezoelectric material in a second axis direction is greater than or equal to a length of the first piezoelectric material in the second axis direction, the second axis direction being orthogonal to the polarization axis and the first axis direction; or a length of the second piezoelectric material in the polarization axis direction is greater than or equal to a length of the first piezoelectric material in the polarization axis direction, and
the optical reflective element further comprises a reflective body that is connected, like a bridge, between distal ends of first driving bodies included in the plurality of actuators, the first driving bodies each being the first driving body.

8. The optical reflective element according to claim 7, further comprising:
a first coupler that integrally couples proximal end portions of first piezoelectric materials included in the plurality of actuators together, the first piezoelectric materials each being the first piezoelectric material.
